(19) United States
(12) Patent Application Publication
(10) Pub. No.: US 2022/0068679 A1
(43) Pub. Date: Mar. 3, 2022

(54) PROCESSING APPARATUS

(71) Applicant: DISCO CORPORATION, Tokyo (JP)

(72) Inventors: Shogo MATSUDA, Tokyo (JP); Yuichiro HAYASHI, Tokyo (JP)

(21) Appl. No.: 17/398,394

(22) Filed: Aug. 10, 2021

(30) Foreign Application Priority Data
Aug. 27, 2020 (JP) 2020-143098

(51) Int. Cl. H01L 21/67; B23K 26/364; B23K 26/03

(52) U.S. Cl. CPC H01L 21/67253; H01L 21/67092; B23K 26/032; B23K 26/364; H01L 21/67115

(57) ABSTRACT

An image capturing unit of a processing apparatus includes a light field camera, an image recorder for recording an image of the workpiece captured by the light field camera, a two-dimensional image processor for generating two-dimensional multi-focal-point images from the image recorded by the image recorder, and a three-dimensional image processor for producing a three-dimensional image by layering the two-dimensional multi-focal-point images. The light field camera includes a main lens, a microlens array having a plurality of microlenses for converging light from the main lens, and an image sensor for capturing the light converged by the microlens array.

### BACKGROUND OF THE INVENTION

### Field of the Invention

The present invention relates to a processing apparatus including a chuck table for holding a workpiece thereon, a processing unit for processing the workpiece held on the chuck table, and an image capturing unit for capturing an image of the workpiece held on the chuck table.

### Description of the Related Art

Wafers with a plurality of devices such as integrated circuits (ICs) and large scale integration (LSI) circuits formed in respective areas demarcated on their face side by a plurality of projected dicing lines are divided along the projected dicing lines into individual device chips by a cutting apparatus having a cutting blade or a laser processing apparatus for applying a laser beam. The device chips produced from the wafers will be used in various electronic appliances including mobile phones, personal computers, and so on.

Images of cut grooves or laser-processed grooves formed in the wafers along the projected dicing lines are captured by an image capturing unit, and the results of the dividing process are inspected. On the basis of the data from the inspection, processing conditions are adjusted by replacing the cutting blade and changing the output power level of the laser beam, for example.

The processing conditions can be adjusted appropriately on the basis of more pieces of information if three-dimensional images of the cut grooves or the laser-processed grooves can be captured. For this reason, the present applicant has proposed a technology for capturing three-dimensional images of cut grooves or laser-processed grooves formed in wafers (see, for example, JP 2015-99026A).

### SUMMARY OF THE INVENTION

According to the technology disclosed in JP 2015-99026A, a number of two-dimensional images have to be generated by moving the focal point of an image capturing unit in order to produce three-dimensional images. Therefore, the disclosed technology remains to be improved in terms of productivity.

It is therefore an object of the present invention to provide a processing apparatus that includes an image capturing unit capable of instantly producing a three-dimensional image of a workpiece processed by the processing apparatus.

In accordance with an aspect of the present invention, there is provided a processing apparatus including a chuck table for holding a workpiece thereon, a processing unit for processing the workpiece held on the chuck table, and an image capturing unit. The image capturing unit includes a light field camera including a main lens, a microlens array having a plurality of microlenses for converging light from the main lens, and an image sensor for capturing the light converged by the microlens array, an image recorder for recording an image of the workpiece captured by the light field camera, a two-dimensional image processor for generating two-dimensional multi-focal-point images from the image recorded by the image recorder, and a three-dimensional image processor for generating a three-dimensional image by layering the two-dimensional multi-focal-point images.

Preferably, the three-dimensional image processor of the image capturing unit produces an image of a three-dimensional shape of a groove formed in the workpiece held on the chuck table. Preferably, the processing unit includes a cutting unit including a cutting blade having an annular cutting edge on an outer circumferential portion thereof and a spindle unit for rotating the cutting blade mounted thereon. Alternatively, the processing unit includes a laser beam applying unit including a laser oscillator for emitting a laser beam and a beam condenser for focusing the laser beam emitted from the laser oscillator.

According to the present invention, a three-dimensional image can be instantly produced from a single image captured of the workpiece by the light field camera for increased productivity. Further, it is possible to produce a plurality of three-dimensional images with different viewpoints on the basis of the image recorded by the image recorder of the image capturing unit.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view of a processing apparatus according to a preferred embodiment of the present invention;

FIG. 2 is a perspective view of a processing unit of the processing apparatus illustrated in FIG. 1;

FIG. 3 is a perspective view of a laser beam applying unit of the processing apparatus illustrated in FIG. 1;

FIG. 4 is a perspective view, partly in block form, of an image capturing unit of the processing apparatus illustrated in FIG. 1;

FIG. 5 is a schematic view of a light field camera of the image processing unit illustrated in FIG. 4;

FIGS. 6A through 6D are schematic views of multi-focal-point images generated by a two-dimensional image processor of the image processing unit illustrated in FIG. 4; and

FIG. 7 is a schematic view of a three-dimensional image produced by a three-dimensional image processor of the image processing unit illustrated in FIG. 4.

### DETAILED DESCRIPTION OF THE PREFERRED EMBODIMENT

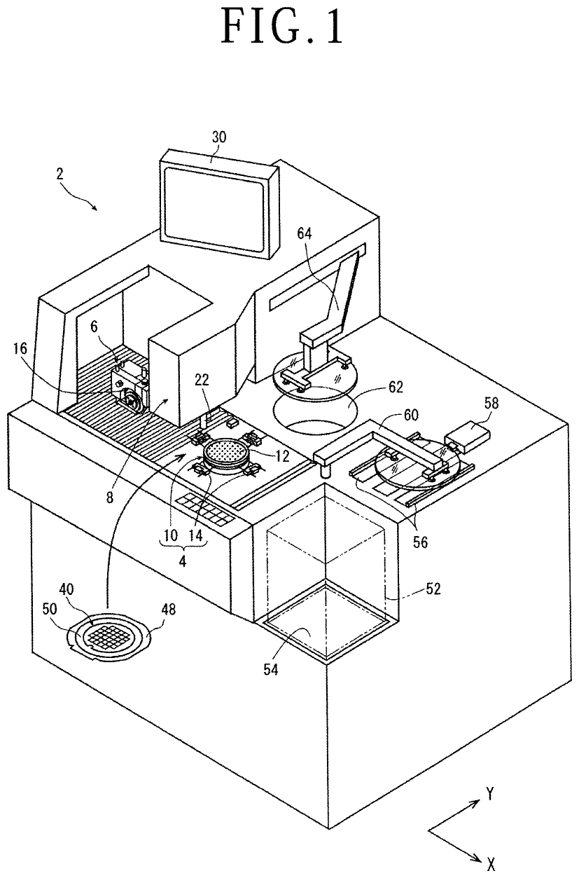

A processing apparatus according to a preferred embodiment of the present invention will be described hereinbelow with reference to the accompanying drawings. As illustrated in FIG. 1, a processing apparatus, generally denoted by 2, includes a holding unit 4 for holding a workpiece to be processed, a processing unit 6 for processing the workpiece held by the holding unit 4, and an image capturing unit 8.

The holding unit 4 includes a chuck table 10 movable in X-axis directions indicated by an arrow X in FIG. 1 and rotatable about its vertical central axis. A porous circular suction chuck 12 is disposed on an upper end of the chuck table 10 and connected to suction means, not illustrated. The suction means generates and applies a suction force to the suction chuck 12 for attracting and holding the workpiece under suction that is placed on an upper surface of the suction chuck 12. The holding unit 4 also includes a plurality of clamps 14 disposed around an outer circumferential edge of the chuck table 10 at circumferentially spaced intervals for clamping an outer circumferential edge of the workpiece on the suction chuck 12. Y-axis directions indicated by an arrow Y in FIG. 1 extend perpendicularly to the X-axis directions. A plane defined by the X-axis directions and the Y-axis directions lies substantially horizontally.

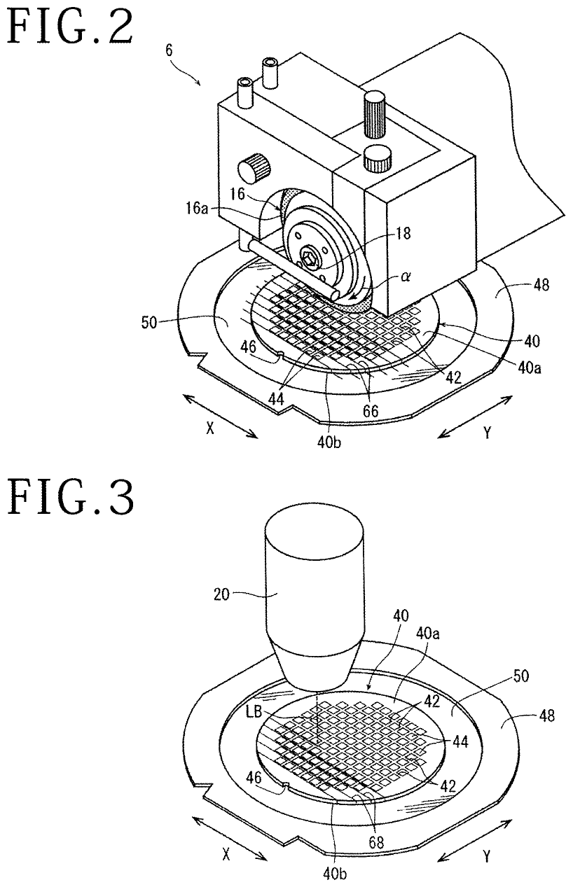

As illustrated in FIGS. 1 and 2, according to the present embodiment, the processing unit 6 includes a cutting unit including a cutting blade 16 having an annular cutting edge 16a on an outer circumferential portion thereof and a spindle 18 for rotating the cutting blade 16 mounted thereon about an axis extending in the Y-axis directions. Alternatively, as illustrated in FIG. 3, the processing unit 6 may include a laser beam applying unit including a beam condenser 20 for focusing a laser beam LB emitted from a laser oscillator, not illustrated.

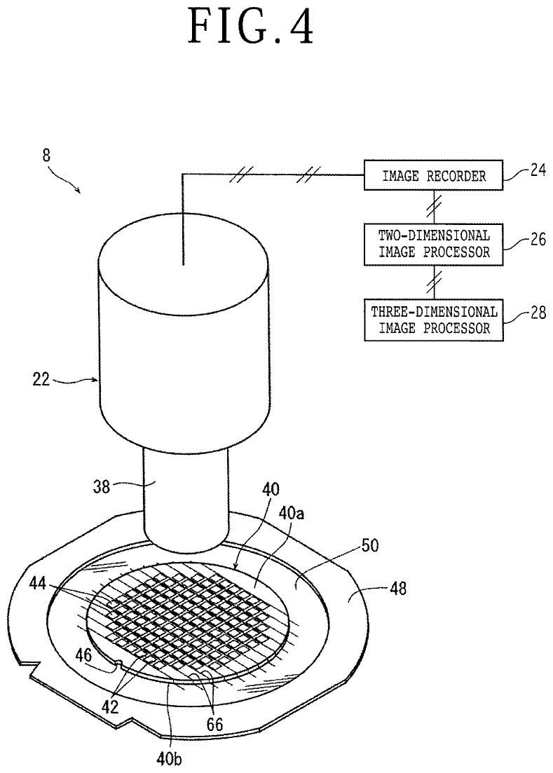

As illustrated in FIG. 1, the image capturing unit 8 is disposed over a track along which the chuck table 10 is movable in the X-axis directions. As illustrated in FIG. 4, the image capturing unit 8 includes a light field camera 22, an image recorder 24 for recording an image captured by the light field camera 22, a two-dimensional image processor 26 for generating two-dimensional multi-focal-point images from the image recorded by the image recorder 24, and a three-dimensional image processor 28 for producing a three-dimensional image by layering the two-dimensional multi-focal-point images. According to the present embodiment, further, the three-dimensional image processor 28 of the image capturing unit 8 produces an image of three-dimensional shapes of grooves formed in the workpiece held by the holding unit 4. The two-dimensional multi-focal-point images generated by the two-dimensional image processor 26, the three-dimensional image produced by the three-dimensional image processor 28, and other images and data are displayed on a display unit 30 (see FIG. 1).

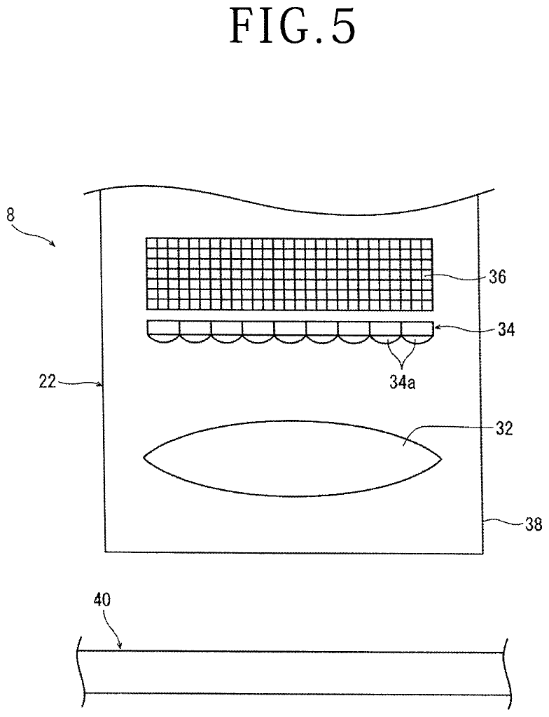

The light field camera 22 of the image capturing unit 8 will be described below with reference to FIG. 5. The light field camera 22 includes a main lens 32, a microlens array 34 having a plurality of microlenses 34a for converging light from the main lens 32, and an image sensor 36 for capturing the light converged by the microlens array 34. The main lens 32, the microlens array 34, and the image sensor 36 are housed in a hollow cylindrical housing 38.

The light field camera 22 captures an image of the workpiece held by the holding unit 4 and acquires image data representing the captured image. The image data acquired by the light field camera 22 are recorded by the image recorder 24. The two-dimensional image processor 26 generates multi-focal-point images, i.e., a plurality of images with different focal points, and multi-viewpoint images, i.e., a plurality of images with different viewpoints, on the basis of the image data recorded by the image recorder 24. The three-dimensional image processor 28 produces a three-dimensional image on the basis of the multi-focal-point images generated by the two-dimensional image processor 26.

Although not illustrated, the image capturing unit 8 includes illuminating means that may include light sources such as a plurality of light-emitting diodes (LEDs) mounted on an outer circumferential portion of a lower end of the housing 38 at circumferentially spaced intervals. Alternatively, the illuminating means may include light sources disposed on an outer circumferential portion of the housing 38 and a half-silvered mirror disposed between the main lens 32 and the microlens array 34 for guiding light from the light sources to the workpiece and guiding light reflected from the workpiece to the image sensor 36.

The workpiece to be processed by the processing apparatus 2 will be described below. FIGS. 1 through 4 illustrate a disk-shaped wafer 40 as the workpiece. As illustrated in FIG. 2, the wafer 40 has a face side 40a including a plurality of rectangular areas demarcated by a grid of projected dicing lines 42 and having a plurality of devices 44 such as ICs and LSI circuits formed in the respective rectangular areas. The wafer 40 also includes a notch 46 defined in a circumferential edge thereof as indicating a crystal orientation of the wafer 40. According to the present embodiment, the wafer 40 has a reverse side 40b opposite the face side 40a, and an adhesive tape 50 having a peripheral edge portion fixed to an annular frame 48 is affixed to the reverse side 40b of the wafer 40.

The processing apparatus 2 will further be described below with reference to FIG. 1. The processing apparatus 2 includes a vertically movable cassette rest base 54 for placing thereon a cassette 52 that houses a plurality of wafers 40 supported on respective annular frames 48 by adhesive tapes 50, a loading/unloading unit 58 for unloading a wafer 40 to be cut from the cassette 52 to a temporary rest table 56 and loading a cut wafer 40 from the temporary rest table 56 into the cassette 52, a first delivery mechanism 60 for delivering the wafer 40 to be cut that is unloaded from the cassette 52 to the temporary rest table 56 to the chuck table 10, a cleaning unit 62 for cleaning the cut wafer 40, and a second delivery mechanism 64 for delivering the cut wafer 40 from the chuck table 10 to the cleaning unit 62.

For dividing a wafer 40 into individual device chips having respective devices 44 on the processing apparatus 2, the loading/unloading unit 58 takes the wafer 40 to be cut from the cassette 52 and places the wafer 40 on the temporary rest table 56. Then, the first delivery mechanism 60 delivers the wafer 40 from the temporary rest table 56 onto the chuck table 10, where the wafer 40 is held under suction, with the face side 40a facing upwardly, on an upper surface of the chuck table 10. The clamps 14 secures the annular frame 48 around the chuck table 10. Then, the chuck table 10 is moved to a position below the image capturing unit 8. The light field camera 22 of the image capturing unit 8 captures an image of the wafer 40 from above the wafer 40. Since the image captured of the wafer 40 by the light field camera 22 is recorded by the image recorder, and the two-dimensional image processor 26 generates two-dimensional multi-focal-point images from the recorded image, it is not necessary to perform focusing at the time the image of the wafer 40 is captured, and it is possible to obtain an image where the face side 40a of the wafer 40 is focused from the multi-focal-point images.

Then, the chuck table 10 is moved to a position below the processing unit 6. On the basis of the image captured of the wafer 40 by the image capturing unit 8, those of the projected dicing lines 42 that extend along a first direction are aligned with the X-axis directions, and the cutting blade 16 is positioned above one of the projected dicing lines 42 aligned with the X-axis directions. Then, as illustrated in FIG. 2, the processing unit 6 is lowered to cause the cutting edge 16a of the cutting blade 16 that is rotating at high speed in the direction indicated by an arrow a to cut into the wafer 40 from the face side 40a to the reverse side 40b, and at the same time, the chuck table 10 is processing-fed in one of the X-axis directions with respect to the processing unit 6, thereby forming a cut groove 66 in the wafer 40 along the projected dicing line 42. Thereafter, the processing unit 6 is indexing-fed in one of the Y-axis directions with respect to the chuck table 10 for a distance commensurate with the pitch of the projected dicing lines 42 in the Y-axis directions. The above cutting process is then carried out again to form another cut groove 66 in the wafer 40 along a next projected dicing line 42. The above process is repeated until cut grooves 66 are formed in the wafer 40 along all the projected dicing lines 42 that extend along the first direction.

Next, in order to confirm the state of the cut grooves 66 formed in the wafer 40 along the projected dicing lines 42, the chuck table 10 is moved to the position below the image capturing unit 8, and the light field camera 22 captures an image of the wafer 40 with the cut grooves 66 formed therein along the projected dicing lines 42 from above the wafer 40. The image recorder 24 records the image data representing the captured image of the wafer 40.

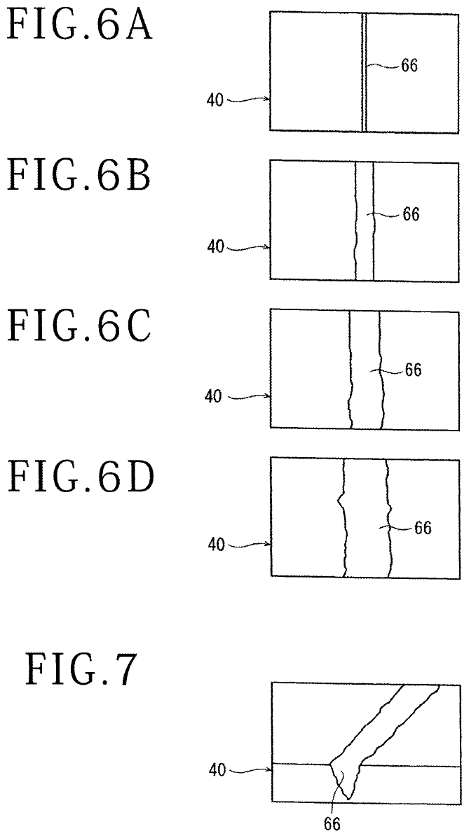

Then, the two-dimensional image processor 26 generates two-dimensional multi-focal-point images from the image data of the wafer 40 with the cut grooves 66 formed therein. FIGS. 6A through 6D schematically illustrate the two-dimensional multi-focal-point images generated by the two-dimensional image processor 26 from one viewpoint covering one of the cut grooves 66. FIG. 6A illustrates an image focused in the vicinity of the bottom of the cut groove 66. FIG. 6B illustrates an image focused on a position above the focused position illustrated in FIG. 6A. FIG. 6C illustrates an image focused on a position above the focused position illustrated in FIG. 6B. FIG. 6D illustrates an image focused on a position above the focused position illustrated in FIG. 6C. Although FIGS. 6A through 6D illustrate four images focused on vertically different positions for illustrative purposes, the two-dimensional image processor 26 can generate any number of two-dimensional images.

Then, the three-dimensional image processor 28 layers the multi-focal-point images generated by the two-dimensional image processor 26 to produce a three-dimensional image of the wafer 40 with the cut grooves 66 formed therein. The display unit 30 displays the multi-focal-point images generated by the two-dimensional image processor 26 and the three-dimensional image produced by the three-dimensional image processor 28 for the operator of the processing apparatus 2 to confirm the state of the cut groove 66. As illustrated in FIG. 7, the display unit 30 also displays a three-dimensional shape of the cut groove 66 formed in the wafer 40, so that the operator can confirm the state of the cut groove 66 in greater detail.

According to the present embodiment, after the operator has confirmed the state of the cut groove 66, the chuck table 10 is moved to the position below the processing unit 6. Then, the chuck table 10 is turned 90 degrees about its vertical central axis to bring other projected dicing lines 42 that extend along a second direction perpendicular to the first direction into alignment with the X-axis directions. The cutting process and the indexing-feed process are repeated until cut grooves 66 are formed in the wafer 40 along all the projected dicing lines 42 extending along the second direction. The wafer 40 is now divided along the cut grooves 66 along all the projected dicing lines 42 into individual device chips having the respective devices 44.

According to the present embodiment, as described above, since the image capturing unit 8 acquires a single unit of image data of the wafer 40 to generate two-dimensional multi-focal point images and then produces a three-dimensional image from the generated two-dimensional multi-focal point images, it is not necessary to capture images of the wafer 40 repeatedly by moving the focal point, resulting in increased productivity.

According to the present embodiment, the state of the cut grooves 66 is confirmed after the cut grooves 66 have been formed in the wafer 40 along all the projected dicing lines 42 that extend along the first direction and are aligned with the X-axis directions. However, the above timing to confirm the state of the cut grooves 66 is not restrictive, but the state of the cut grooves 66 may be confirmed at other times, e.g., after a cut groove 66 has been formed in the wafer 40 along one of the projected dicing lines 42. According to the present embodiment, further, the cut grooves 66 are formed by the cutting unit including the cutting blade 16 and the state of the cut grooves 66 is confirmed. However, as illustrated in FIG. 3, the laser beam LB that is absorbable by the wafer 40 may be applied to the wafer 40 along the projected dicing lines 42 to form laser-processed grooves 68 in the wafer 40 by way of ablation, and the state of the laser-processed grooves 68 may be confirmed.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A processing apparatus comprising:
a chuck table for holding a workpiece thereon;
a processing unit for processing the workpiece held on the chuck table; and
an image capturing unit,
wherein the image capturing unit includes
a light field camera including a main lens, a microlens array having a plurality of microlenses for converging light from the main lens, and an image sensor for capturing the light converged by the microlens array,
an image recorder for recording an image of the workpiece captured by the light field camera,
a two-dimensional image processor for generating two-dimensional multi-focal-point images from the image recorded by the image recorder, and
a three-dimensional image processor for generating a three-dimensional image by layering the two-dimensional multi-focal-point images.

2. The processing apparatus according to claim 1,
wherein the three-dimensional image processor of the image capturing unit produces an image of a three-dimensional shape of a groove formed in the workpiece held on the chuck table.

3. The processing apparatus according to claim 1,
wherein the processing unit includes a cutting unit including a cutting blade having an annular cutting edge on an outer circumferential portion thereof and a spindle for rotating the cutting blade mounted thereon.

4. The processing apparatus according to claim 1,
wherein the processing unit includes a laser beam applying unit including a laser oscillator for emitting a laser beam and a beam condenser for focusing the laser beam emitted from the laser oscillator.
